(19) United States
(12) Patent Application Publication
(10) Pub. No.: US 2012/0149208 A1
(43) Pub. Date: Jun. 14, 2012

(54) SUBSTRATE PROCESSING APPARATUS AND METHOD OF MANUFACTURING SEMICONDUCTOR DEVICE

(75) Inventor: Takahito NAKAJIMA, Mie (JP)

(73) Assignee: KABUSHIKI KAISHA TOSHIBA, Tokyo (JP)

(21) Appl. No.: 13/238,175

(22) Filed: Sep. 21, 2011

(30) Foreign Application Priority Data
Dec. 13, 2010 (JP) 2010-276846

(51) Int. Cl. H01L 21/306; B08B 1/00

(52) U.S. Cl. 438/745; 15/97.1; 257/E21.219

(57) ABSTRACT

According to one embodiment, a substrate processing apparatus includes a substrate support unit configured to support a substrate by fixing the substrate from a back surface side of a surface to be processed; and a substrate processing unit in which a pad into which a predetermined liquid is soaked is arranged and which performs a substrate process on the surface to be processed of the substrate with the liquid. The surface to be processed of the substrate is brought into contact with the liquid on the pad surface by bringing the surface to be processed of the substrate close to a side of the pad, without rotating the substrate and the pad, to perform a substrate process.

### CROSS-REFERENCE TO RELATED APPLICATIONS

This application is based upon and claims the benefit of priority from the prior Japanese Patent Application No. 2010-276846, filed on Dec. 13, 2010; the entire contents of which are incorporated herein by reference.

### FIELD

An embodiment described herein relates generally to a substrate processing apparatus and a method of manufacturing a semiconductor device.

### BACKGROUND

In a process for manufacturing a semiconductor device, various types of substrate processes (cleaning, etching, etc.) are applied on the surface of a substrate on which the semiconductor device is formed. For example, when CMP (Chemical Mechanical Polishing) is performed as a substrate processing of the substrate, the substrate is pressed against the surface of a pad. Then, the substrate is rotated within a substrate surface where the center of the substrate is used as a rotation shaft, and at the same time, the pad is rotated within a pad surface where the center of the pad is used as a rotation shaft.

However, in the CMP, as a result of the substrate or the pad being rotated, the pad applies a great force to the substrate surface. Thus, in the CMP, it is difficult to clean or etch the substrate surface without damaging an on-substrate pattern formed on the substrate. In view of such a circumstance, a method of performing a substrate process by minimizing the damage applied to the on-substrate pattern is desired.

### BRIEF DESCRIPTION OF THE DRAWINGS

FIG. 1 is a diagram illustrating the configuration of a substrate processing apparatus according to an embodiment;

FIG. 2 is a diagram illustrating a first configuration example of a substrate processing unit;

FIG. 3 is a diagram illustrating a second configuration example of the substrate processing unit;

FIGS. 4A through 4D are diagrams each explaining behavior of an HF solution when an HF solution process is performed on a wafer;

FIGS. 5A through 5C are diagrams each explaining behavior of water when drying process is performed on the wafer;

FIG. 6 is a diagram illustrating the configuration of a drying mechanism when a drying pad is vacuumed by a vacuum pump; and

FIG. 7 is a diagram explaining a mechanism for supplying liquid to a pad.

### DETAILED DESCRIPTION

In general, according to one embodiment, a substrate processing apparatus includes a substrate support unit configured to support a substrate by fixing it from a back surface side of a surface to be processed. The substrate processing apparatus also includes a substrate processing unit in which a pad into which a predetermined liquid is soaked is arranged and which performs a substrate process on the surface to be processed of the substrate with the liquid. When the substrate process is performed, the substrate support unit configured to support the substrate is brought close to the pad side. As a result, the surface to be processed of the substrate is brought into contact with the liquid on the pad surface without rotating the substrate and the pad. In this way, the substrate process is performed without rotating the substrate and the pad.

Exemplary embodiments of a substrate processing apparatus and a method of manufacturing a semiconductor device will be explained below in detail with reference to the accompanying drawings. The present invention is not limited to the following embodiments.

### EMBODIMENT

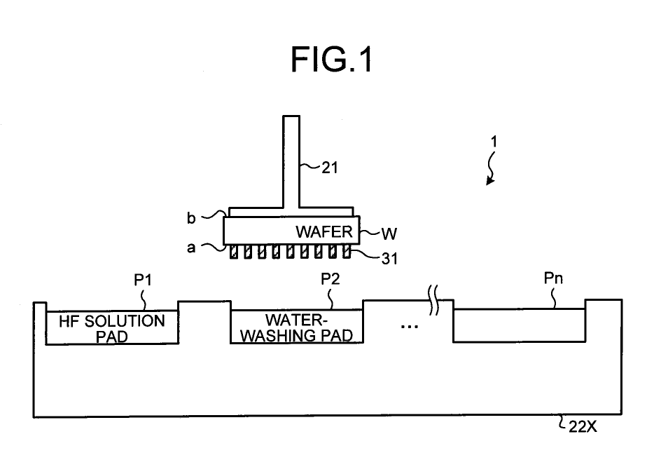

FIG. 1 is a diagram illustrating the configuration of a substrate processing apparatus according to the embodiment. FIG. 1 illustrates a configuration example of the cross-section of the substrate processing apparatus 1. The substrate processing apparatus 1 is of single-wafer-processing type in which a substrate process is performed on a substrate (such as a wafer W) on which a semiconductor device is formed. The substrate processing apparatus 1 is configured to include a substrate support unit 21 and a substrate processing unit 22X.

The substrate support unit 21 supports a wafer W by fixing it from a back surface b side, which is opposite to a surface to be processed (surface a) of the wafer W. The substrate support unit 21 supports the wafer W by vacuum-drawing the wafer W from the back surface b side, for example. The substrate support unit 21 may support the wafer W by contacting a side surface of the wafer W. In this case, the substrate support unit 21 fixes the wafer W by pressing a pin unit (not illustrated) against the side surface of the wafer W at a plurality of locations. The substrate support unit 21 supports the wafer W so that the surface a of the wafer W faces a side of the substrate processing unit 22X.

The substrate processing unit 22X includes at least one pad. FIG. 1 illustrates a case where an HF solution pad P1, a water-washing pad P2, . . . , and a pad Pn (n is a natural number) are arranged in the substrate processing unit 22X. In the below description, any one of or a plurality of the HF solution pad P1, the water-washing pad P2, . . . , and the pad Pn may be referred to as “pad Px”.

The substrate process performed by each pad Px on the surface a of the wafer W includes an HF solution process, a water-washing process, and a drying process described later. For example, an HF solution is soaked into the HF solution pad P1, and water for washing is soaked into the water-washing pad P2. As a result, the substrate process is performed on the surface a of the wafer W with the HF solution or water.

In the substrate processing unit 22X, a dent (storage hole) in which the pad Px is stored is opened at a location where each pad Px is arranged, and each pad Px is arranged in this storage hole. The storage hole in which each pad Px is arranged is formed deeper than the thickness of each pad Px. As a result, even when liquid such as the HF solution or water is soaked into each pad Px, it is possible to prevent the liquid such as the HF solution and water from flowing to a region other than the region where each pad Px is arranged.

On the surface a of the wafer W, an on-wafer pattern 31 having a predetermined height is formed. In the substrate processing apparatus 1, when the substrate process of the wafer W is performed, the wafer W is supported from the bottom surface b side by the substrate support unit 21. Then, when the substrate support unit 21 supporting the wafer W is brought close to any one of pads Px side, the on-wafer pattern 31 (surface a, which is a surface to be processed) of the wafer W is brought into contact with the liquid on the surface of the pad Px without rotating the wafer W and the pad Px. As a result, the substrate process of the wafer W is performed by the liquid of the pad Px without rotating the wafer W and the pad Px.

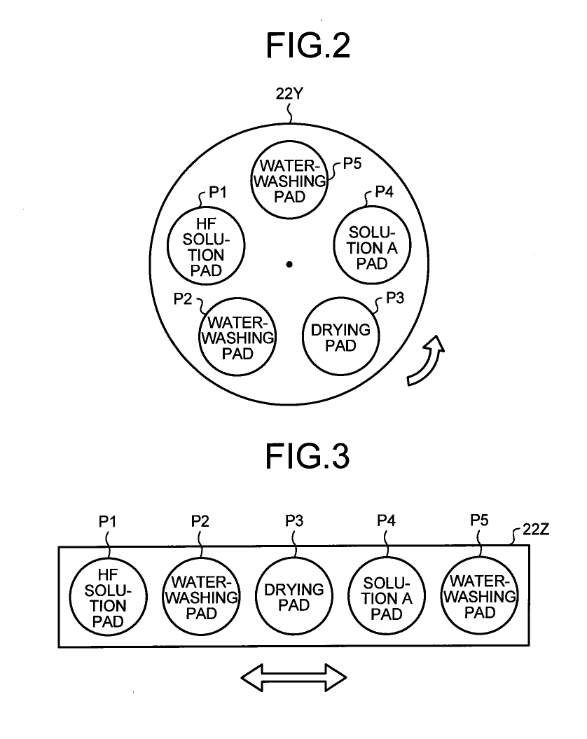

FIG. 2 is a diagram illustrating a first configuration example of the substrate processing unit. FIG. 2 illustrates an upper surface diagram of a substrate processing unit 22Y, as a diagram illustrating a first configuration example of the substrate processing unit 22X. Herein, a case where the substrate processing unit 22Y includes five pads as the pad Px is described.

In the substrate processing unit 22Y, the HF solution pad P1, the water-washing pad P2, a drying pad P3, a solution A pad P4, and a water-washing pad P5 are arranged, for example. The HF solution pad P1 and the water-washing pad P2 are pads configured to perform an HF solution process and a water-washing process, respectively, as described in FIG. 1. The water-washing pad P5 is configured to perform a water-washing process, similarly to the water-washing pad P2.

The drying pad P3 is a pad configured to dry the surface a of the wafer W. Therefore, the drying pad P3 is kept dry without soaking liquid into the drying pad P3. The solution A pad P4 is a pad configured to perform a solution process of the wafer W with a solution A.

In each pad Px, its main surface is in an approximately circular shape, similarly to the wafer W. The in-plane size of each pad Px is larger than the in-plane size of the wafer W. In other words, each pad Px has a main surface region larger than the entire surface of the substrate such as the wafer W, and as a result, it is possible to bring the entire surface of the wafer W into contact or close to the pad Px.

The substrate processing unit 22Y has a main surface region in an approximately circular shape, and on the main surface region, each pad Px is arranged. In the substrate processing unit 22Y, each pad Px is arranged in a ring shape at approximately equal intervals so that a distance from a center portion of the substrate processing unit 22Y is approximately equal.

The substrate processing unit 22Y is configured to rotate in an in-plane direction around the center of its main surface region, as a rotation shaft. When the substrate process is started, the substrate processing unit 22Y is rotated around the center of the substrate processing unit 22Y, as a rotation shaft, and thereby, each pad Px is moved in the same plane as the main surface of the substrate processing unit 22Y. As a result, a desired pad Px is moved beneath the wafer W.

When a plurality of types of substrate processes are performed, the desired pad is moved beneath the wafer W according to an order in which the pad Px used for the substrate process is subject to a substrate process. In this way, the surface a of the wafer W is brought into contact or close to each pad Px in order.

For example, by rotating the substrate processing unit 22Y, the HF solution pad P1 is moved beneath the wafer W. Thereafter, the surface a of the wafer W is brought close to the HF solution pad P1 and the HF process is performed on the wafer W.

Then, the wafer W is lifted up above the HF solution pad P1. This is followed by rotation of the substrate processing unit 22Y. As a result, the water-washing pad P2 is moved beneath the wafer W. Thereafter, the surface a of the wafer W is brought close to the water-washing pad P2 and the water-washing process is performed on the wafer W.

Subsequently, the wafer W is lifted up above the water-washing pad P2. Then, the substrate processing unit 22Y is rotated. As a result, the drying pad P3 is moved beneath the wafer W. Thereafter, the surface a of the wafer W is brought into contact with the drying pad P3 and the drying process is performed on the wafer W.

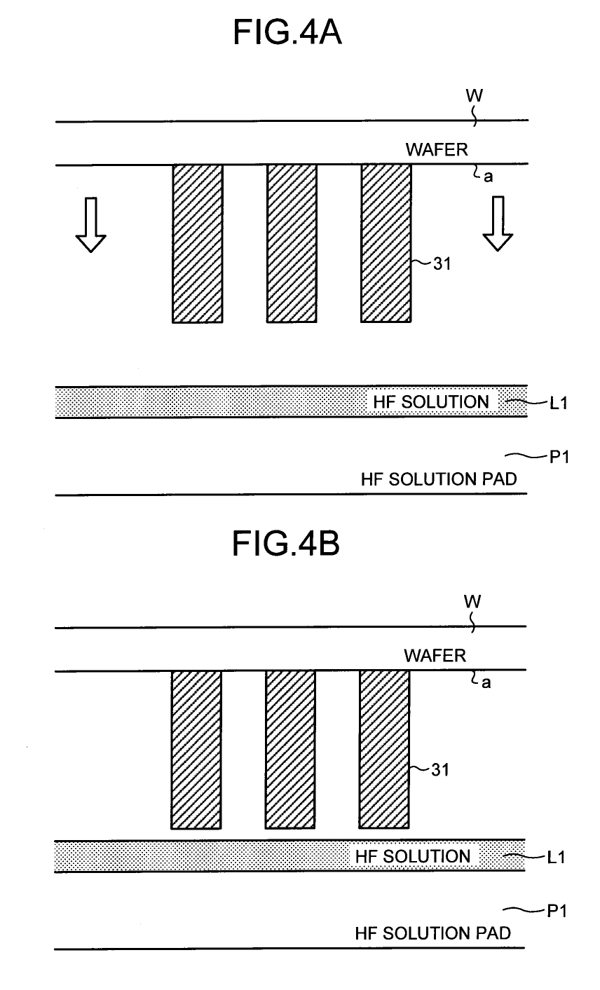

FIG. 3 is a diagram illustrating a second configuration example of the substrate processing unit. FIG. 3 illustrates an upper surface diagram of a substrate processing unit 22Z, as a diagram illustrating a second configuration example of the substrate processing unit 22X. Herein, a case where the substrate processing unit 22Z includes five pads as the pad Px is described. In the substrate processing unit 22Z, the HF solution pad P1, the water-washing pad P2, the drying pad P3, the solution A pad P4, and the water-washing pad P5 are arranged, for example, similarly to the substrate processing unit 22Y.

The substrate processing unit 22Z has a main surface region in an approximately rectangular shape, and on the main surface region in an approximately rectangular shape, each pad Px is arranged. In the substrate processing unit 22Z, each pad Px is arranged at approximately equal intervals in a straight line manner in a lengthwise direction of the main surface region.

The substrate processing unit 22Z includes a belt conveyor-type pad moving function. Specifically, the substrate processing unit 22Z is configured to reciprocate in the same direction as the straight line direction in which each pad Px is lined. When the substrate process is started, the substrate processing unit 22Z is moved in a straight line direction in which each pad Px is lined, and in this way, each pad Px is moved in the same in-plane as the main surface of the substrate processing unit 22Z. As a result, a desired pad Px is moved beneath the wafer W.

When a plurality of types of substrate processes are performed, the desired pad is moved beneath the wafer W according to an order in which the pad Px used for the substrate process is subject to a substrate process. In this way, the surface a of the wafer W is brought into contact or close to each pad Px in order.

For example, by moving the substrate processing unit 22Z in a straight line, the HF solution pad P1 is moved beneath the wafer W. Thereafter, the surface a of the wafer W is brought close to the HF solution pad P1 and the HF process is performed on the wafer W.

Then, the wafer W is lifted up above the HF solution pad P1. This is followed by moving the substrate processing unit 22Z in a straight line. As a result, the water-washing pad P2 is moved beneath the wafer W. Thereafter, the surface a of the wafer W is brought close to the water-washing pad P2 and the water-washing process is performed on the wafer W.

Subsequently, the wafer W is lifted up above the water-washing pad P2. This is followed by moving the substrate processing unit 22Z in a straight line. As a result, the drying pad P3 is moved beneath the wafer W. Thereafter, the surface a of the wafer W is brought into contact with the drying pad P3 and the drying process is performed on the wafer W.

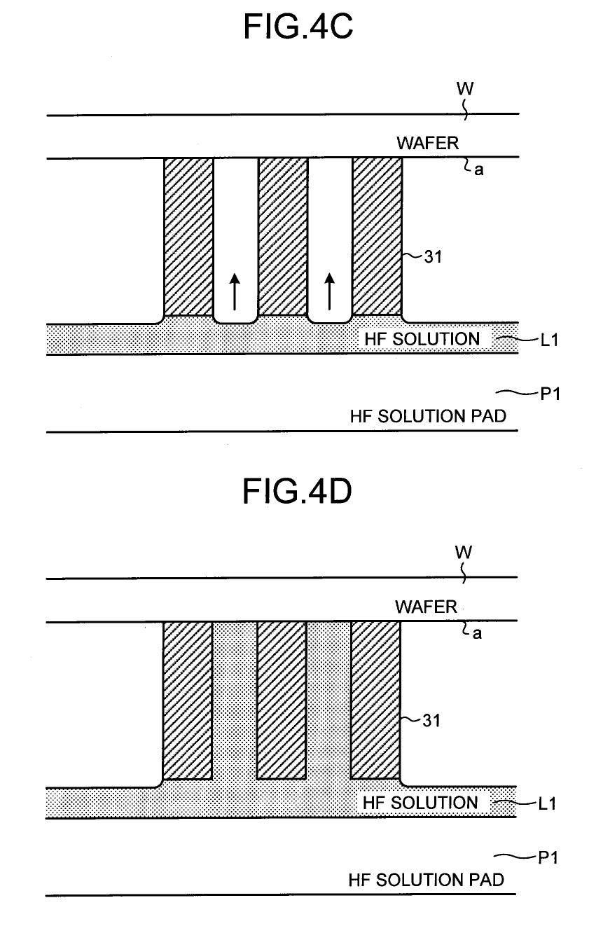

Subsequently, the movement operation of the wafer W and behavior of liquid (solution or water) during the substrate process are described. Firstly, a case where the substrate process is the HF solution process is described. FIGS. 4A through 4D are diagrams each explaining behavior of the HF solution when the HF solution process is performed on the wafer.

The substrate processing apparatus 1 moves the HF solution pad P1 beneath the wafer W when performing the HF solution process on the wafer W. Then, the substrate support unit 21 supporting the wafer W is descended to the HF solution pad P1 side. As a result, the on-wafer pattern 31 of the wafer W is brought close to the HF solution pad P1 side, as illustrated in FIG. 4A.

The HF solution pad P1 is filled with an HF solution L1, and the HF solution L1 is seeped onto the surface of the HF solution pad P1. As illustrated in FIG. 4B, the substrate processing apparatus 1 descends the substrate support unit 21 until a distance between the on-wafer pattern 31 and the HF solution pad P1 or the HF solution L1 is equal to or less than a predetermined value.

When the on-wafer pattern 31 contacts the HF solution L1, the substrate processing apparatus 1 stops descending the substrate support unit 21. As a result, as illustrated in FIG. 4C, the HF solution L1 is drawn to the on-wafer pattern 31 due to the surface tension of the HF solution L1. Thus, in this embodiment, the surface a is brought into contact with the liquid on the surface of the pad Px by using the surface tension of the liquid, without bringing the surface a of the wafer W (on-wafer pattern 31) into contact with the pad Px itself.

Thereafter, this state is continue to maintained without moving the position of the wafer W and the HF solution pad P1. As a result, as illustrated in FIG. 4D, the HF solution L1 of the HF solution pad P1 penetrates through the interior of the on-wafer pattern 31 due to a capillary action. Moreover, this state is continued to maintain over a predetermined time period without moving the position of the wafer W and the HF solution pad P1. As a result, the HF process is performed on the wafer W with the HF solution L1.

It is noted that when the substrate processing apparatus 1 performs a water-washing process on the wafer W, a process similar to that when the HF solution process is performed on the wafer W is performed also. Specifically, after the HF solution L1 and the water held between the patterns on wafer 31 are mixed and diluted, the HF solution L1 and the water are substituted so as to perform a water-washing process between the patterns on wafer 31. In this case also, the surface a is brought into contact with the liquid on the surface of the pad Px by using the surface tension of the liquid, without bringing the surface a of the wafer W (on-wafer pattern 31) into contact with the pad Px itself.

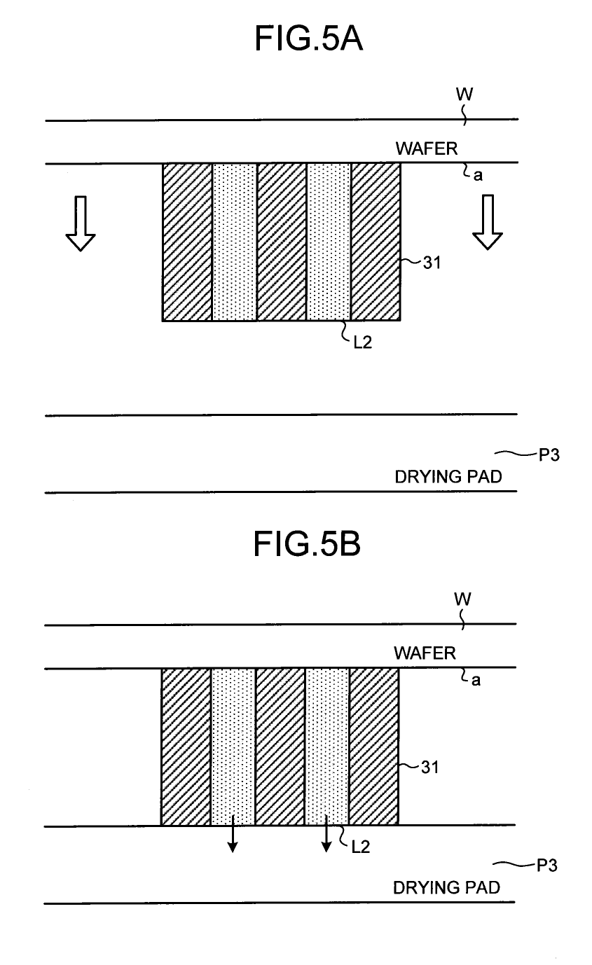

Subsequently, the movement operation of the wafer W and the behavior of the liquid (water) in a case where the substrate process is the drying process of the wafer W are described. FIGS. 5A through 5C are diagrams each explaining the behavior of water when the drying process is performed on the wafer.

For example, when water-washing process is performed on the wafer W after performing the HF solution process on the wafer W, water L2 adheres onto the surface a of the wafer W. The substrate processing apparatus 1 moves the drying pad P3 beneath the wafer W when performing the drying process on the wafer W. Then, the substrate support unit 21 supporting the wafer W is descended to the drying pad P3 side. As a result, the on-wafer pattern 31 of the wafer W is brought close to the drying pad P3, as illustrated in FIG. 5A.

As illustrated in FIG. 5B, the substrate processing apparatus 1 stops the descending of the substrate support unit 21 when the pattern on water 31 contacts the drying pad P3. When the on-wafer pattern 31 contacts the drying pad P3, this state is continued to maintain without moving the position of the wafer W and the drying pad P3. As illustrated in FIG. 5C, as a result of the on-wafer pattern 31 contacting the drying pad P3, the drying pad P3 absorbs the water L2 in the vicinity of the on-wafer pattern 31. Thereby, the substrate processing apparatus 1 dries the wafer W.

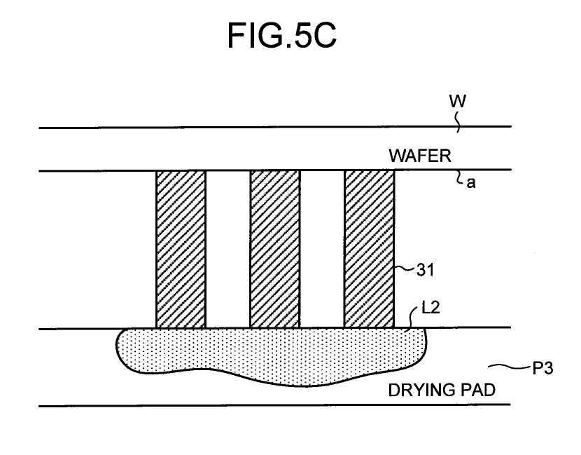

It is noted that when performing the drying process on the wafer W by the drying pad P3, the drying pad P3 may be vacuumed by a vacuum pump. FIG. 6 is a diagram illustrating the configuration of a drying mechanism when the drying pad is vacuumed by a vacuum pump. The drying mechanism is configured to include a vacuum pump 40, a vacuum pipe 42, a suction unit 41, and the drying pad P3. When the drying pad P3 is vacuumed by the vacuum pump 40, the vacuum pump 40 is connected to the bottom of the drying pad P3, for example, with the vacuum pipe 42 and the suction unit 41 being interposed therebetween.

At the bottom of the storage hole of the drying pad P3, at least one hole for vacuum is arranged. Then, the hole for vacuum is connected to the suction unit 41, and the suction unit 41 is connected to the vacuum pump 40 with the vacuum pipe 42 being interposed therebetween.

The water L2, etc., absorbed by the drying pad P3 are suctioned by the suction unit 41, and forwarded to the vacuum pump 40 through the vacuum pipe 42. Then, the water L2, etc., are discharged from the vacuum pump 40. As a result, it is possible to maintain a drying state of the drying pad P3.

It is noted that the hole for vacuum may be arranged on the side surface side or the upper surface side of the drying pad P3. In this case, the suction unit 41 is connected to the hole for vacuum arranged on the side surface side or the upper surface side of the drying pad P3.

Subsequently, a method of supplying liquid to the pad Px is described. It is noted that the method of supplying solution to the pad Px is the same irrespective of the types of liquids, and therefore, a method of supplying an HF solution to the HF solution pad P1 is described.

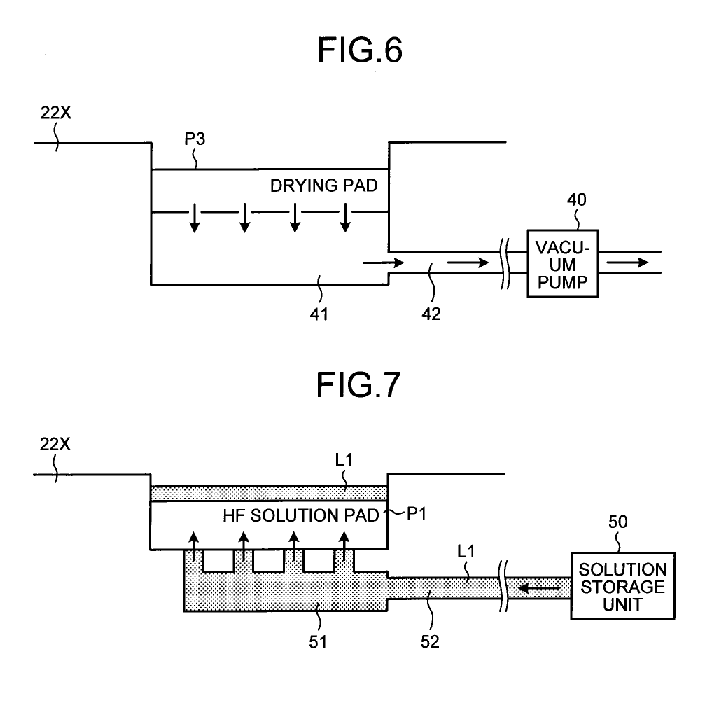

FIG. 7 is a diagram explaining a mechanism for supplying liquid to a pad. The liquid supplying mechanism includes a solution storage unit 50 configured to store an HF solution L1, a solution supplying unit 51, and a solution pipe 52. The solution storage unit 50 is a tank in which the HF solution L1 is stored, for example, and is connected to the bottom of the HF solution pad Pl, for example, with the solution pipe 52 and the solution supplying unit 51 being interposed therebetween.

At the bottom surface of the storage hole of the HF solution pad P1, at least one hole (solution supplying hole) configured to supply the HF solution L1 is arranged. Then, the solution supplying hole is connected to the solution supplying unit 51, and the solution supplying unit 51 is connected to the solution storage unit 50 with the solution pipe 52 being interposed therebetween.

The HF solution L1 forwarded from the solution storage unit 50 is forwarded to the solution supplying unit 51 through the solution pipe 52. Then, from the solution supplying unit 51, the HF solution L1 is forwarded to the HF solution pad P1 through the solution supplying hole. As a result, it is possible to fill the HF solution pad P1 with the HF solution L1.

It is noted that the solution supplying hole may be arranged at the side surface side or the upper surface side of the HF solution pad P1. In this case, the solution supplying unit 51 is connected to the solution supplying hole arranged at the side surface side or the upper surface side of the HF solution pad P1.

The substrate process on the wafer W by the substrate processing apparatus 1 is implemented by various steps carried out during manufacturing a semiconductor device. For example, the wafer W coated with a resist is exposed by using a photo mask. Thereafter, the wafer W is developed, and as a resist pattern, the on-wafer pattern 31 is formed on the wafer W. Then, during etching the lower layer side of the wafer W by using the resist pattern as a mask, the HF solution process by the HF solution pad P1, the water-washing process by the water-washing pad P2, the drying process by the drying pad P3, etc., are performed. As a result, an actual pattern corresponding to the resist pattern is formed on the wafer W. During manufacturing a semiconductor device, the above-described exposure process, the development process, the substrate process, etc., are repeated for each layer.

In addition to the resist pattern, the on-wafer pattern 31 may be a pattern formed by using another film. Moreover, the substrate process may be implemented more than once in each layer of the wafer process. The substrate process may include not only etching using a resist pattern or a hard mask, but also a process of thinning a pattern.

As described above, in this embodiment, the substrate process is performed on the wafer W by bringing the on-wafer pattern 31 into contact with the liquid on the surface of the pad Px without rotating the pad Px. During performing the substrate process of the wafer W, the on-wafer pattern 31 is brought into contact with the liquid on the surface of the pad Px by using the surface tension of the liquid, without bringing the on-wafer pattern 31 into contact with the pad Px itself. Thus, a force is not applied to the on-wafer pattern 31 from the pad Px during the substrate process, and therefore, it is possible to prevent a destruction (pattern collapse) of the on-wafer pattern 31.

During performing the substrate process, the liquid soaked into the pad Px is penetrated through the interior of the on-wafer pattern 31 by way of a capillary action. When the pad Px is used, a need of filling a liquid solution in a process tank is eliminated, and therefore, as compared to a case where the liquid solution is filled in the process tank, it is possible to reduce an amount of solution to be used. Specifically, even with an amount by which a solution layer is not formed in the process tank, if the solution is soaked into the pad Px, then it is possible to perform a substrate surface process on a wafer in-plane uniformly with a small amount of liquid. Moreover, the substrate process is performed on the wafer W without rotating the pad Px, and therefore, it is possible to prevent dust and water glass (water droplet) from adhering to the wafer W.

Moreover, the substrate processing unit 22X includes a plurality of pads Px, and thus, even when performing a plurality of types of substrate processes, it is possible to shorten a time period between a substrate process and a next substrate process. This facilitates process control (etching control, etc.) on the wafer W. Further, there are provided the water-washing pads P2, P5, etc., and thus, if the water-washing process is executed between an acid solution process and an alkaline solution process, then it is possible to continuously execute the both processes, i.e., the acid solution process and the alkaline solution process.

It is noted that in this embodiment, the pad Px is moved so as to move the desired pad Px beneath the wafer W; however, the substrate support unit 21 may move the wafer W above the desired pad Px. Moreover, when the solutions are exchanged, a new solution may be soaked after suctioning the used solution from the back surface side of the pad Px, or the solution may be exchanged with the used pad Px.

In this embodiment, during performing the HF solution process or the water-washing process as the substrate process on the wafer W, the on-wafer pattern 31 is not brought into contact with the pad Px; however, the substrate process may be performed by bringing the on-wafer pattern 31 into contact with the pad Px. In this case, the on-wafer pattern 31 is pressed against the pad Px with a predetermined pressing force.

In this embodiment, the pad Px is not rotated during the substrate process; however, the pad Px may be moved along a direction in which the on-wafer pattern 31 (direction parallel to a line pattern) extends. The wafer W may be moved along a direction in which the on-wafer pattern 31 extends. When the on-wafer pattern 31 extends in various directions, the pad Px or the wafer W are moved along a direction in which a pattern in which many patterns such as a memory cell are arranged extends, for example. Moreover, the pad Px or the wafer W may be moved along a direction in which a pattern that is highly likely to experience a pattern destruction extends.

According to the embodiment, the substrate process is performed on the wafer W without rotating the wafer W and the pad Px, and therefore, it is possible to minimize the damage that results from the substrate processing, of the wafer W.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing apparatus, comprising:
a substrate support unit configured to support a substrate by fixing the substrate from a back surface side of a surface to be processed; and
a substrate processing unit in which a pad into which a predetermined liquid is soaked is arranged and which performs a substrate processing on the surface to be processed of the substrate with the liquid, wherein
when performing the substrate processing, the surface to be processed of the substrate is brought into contact with the liquid on the pad surface by bringing the substrate support unit configured to support the substrate close to a side of the pad, without rotating the substrate and the pad, to perform the substrate processing without rotating the substrate and the pad.

2. The substrate processing apparatus according to claim 1, wherein
the pad includes a plurality of pads, and
when performing the substrate processing, the surface to be processed of the substrate is brought into contact with the liquid on each pad surface according to an order that the substrate is processed.

3. The substrate processing apparatus according to claim 2, wherein
in the substrate processing unit, each pad is arranged in a ring shape so that a distance from a center portion is equal within a region in an approximately circular shape, and
when performing the substrate processing, each pad is rotated and moved by using the center portion of the approximately circular shape as a rotation shaft, to bring the surface to be processed of the substrate into contact with the liquid on each pad surface according to an order that the substrate is processed.

4. The substrate processing apparatus according to claim 2, wherein
in the substrate processing unit, each pad is arranged in a straight line, and
when performing the substrate processing, each pad is moved in the same direction as a straight line direction in which each pad is lined, to bring the surface to be processed of the substrate into contact with the liquid on each pad surface according to an order that the substrate is processed.

5. The substrate processing apparatus according to claim 1, wherein when performing the substrate processing, the surface to be processed of the substrate is brought into contact with the liquid on the pad surface by using a surface tension of the liquid, without bringing the surface to be processed of the substrate into contact with the pad itself.

6. The substrate processing apparatus according to claim 1, wherein when performing the substrate processing, the surface to be processed of the substrate is pressed against the pad with a predetermined pressing force, and at the same time, the surface to be processed is brought into contact with the liquid on the pad surface by using a surface tension of the liquid.

7. The substrate processing apparatus according to claim 1, wherein the substrate processing unit includes, as the pad, at least one of a water-washing pad configured to wash the surface to be processed of the substrate with water and a solution pad configured to perform a solution processing on the surface to be processed of the substrate.

8. The substrate processing apparatus according to claim 1, further comprising a liquid storage unit in which the liquid is stored, wherein
the liquid storage unit supplies the substrate processing unit with the liquid from a liquid supplying hole arranged in the substrate processing unit.

9. The substrate processing apparatus according to claim 1, further comprising an absorption processing unit in which a drying pad configured to absorb liquid on the substrate is arranged and which absorbs the liquid from the surface to be processed of the substrate by the drying pad, wherein
when absorbing the liquid, the substrate supporting unit configured to support the substrate is brought close to a side of the drying pad, to bring the surface to be processed of the substrate into contact with the drying pad.

10. The substrate processing apparatus according to claim 1, further comprising a vacuum pump configured to vacuum the liquid absorbed by the absorption processing unit through a vacuum pipe, wherein
the vacuum pump vacuums the liquid absorbed by the absorption processing unit from a hole for vacuum arranged in the absorption processing unit.

11. A method of manufacturing a semiconductor device, comprising:
supporting a substrate by fixing the substrate from a back surface side of a surface to be processed;
performing a substrate processing on a surface to be processed of the substrate with the liquid on the pad into which a predetermined liquid is soaked; and
forming an on-substrate pattern on the substrate by using the substrate on which the substrate processing has been performed, wherein
when performing the substrate processing, the surface to be processed of the substrate is brought into contact with the liquid on the pad surface by bringing the surface to be processed of the substrate close to a side of the pad, without rotating the substrate and the pad, to perform the substrate processing without rotating the substrate and the pad.

12. The method of manufacturing a semiconductor device according to claim 11, wherein
the pad includes a plurality of pads, and
when performing the substrate processing, the surface to be processed of the substrate is brought into contact with the liquid on each pad surface according to an order that the substrate is processed.

13. The method of manufacturing a semiconductor device according to claim 12, wherein
each pad is arranged in a ring shape so that a distance from a center portion is equal within a region in an approximately circular shape, and
when performing the substrate processing, each pad is rotated and moved by using the center portion of the approximately circular shape used as a rotation shaft, to bring the surface to be processed of the substrate into contact with the liquid on each pad surface according to an order that the substrate is processed.

14. The method of manufacturing a semiconductor device according to claim 12, wherein
each pad is arranged in a straight line, and
when performing the substrate processing, each pad is moved in the same direction as a straight line direction in which each pad is lined, to bring the surface to be processed of the substrate into contact with the liquid on each pad surface according to an order that the substrate is processed.

15. The method of manufacturing a semiconductor device according to claim 11, wherein when performing the substrate processing, the surface to be processed of the substrate is brought into contact with the liquid on the pad surface by using a surface tension of the liquid, without bringing the surface to be processed of the substrate into contact with the pad itself.

16. The method of manufacturing a semiconductor device according to claim 11, wherein when performing the substrate processing, the surface to be processed of the substrate is pressed against the pad with a predetermined pressing force, and at the same time, the surface to be processed is brought into contact with the liquid on the pad surface by using a surface tension of the liquid.

17. The method of manufacturing a semiconductor device according to claim 11, wherein the pad includes at least one of a water-washing pad configured to wash the surface to be processed of the substrate with water and a solution pad configured to perform a solution processing on the surface to be processed of the substrate.

18. The method of manufacturing a semiconductor device according to claim 11, wherein after the substrate processing, the surface to be processed of the substrate is brought into contact with a drying pad configured to absorb the liquid on the substrate.
